(19) United States
(12) Patent Application Publication
(10) Pub. No.: US 2026/0015712 A1
(43) Pub. Date: Jan. 15, 2026

(54) Detachable Mid Temp Electrostatic Chuck (ESC) for Process Chamber

(71) Applicant: Applied Materials, Inc., Santa Clara, CA (US)

(72) Inventors: Sarath BABU, Singapore (SG); Mukund SUNDARARAJAN, Bangalore (IN); Ananthkrishna JUPUDI, Singapore (SG); Cheng-Hsiung Matthew TSAI, Cupertino, CA (US); Shane LAVAN, Santa Clara, CA (US)

(21) Appl. No.: 18/771,966

(22) Filed: Jul. 12, 2024

(51) Int. Cl. C23C 14/50; C23C 14/54

(52) U.S. Cl. CPC C23C 14/50; C23C 14/541

(57) ABSTRACT

Embodiments of substrate supports are provided herein. In some embodiments, a substrate support includes: a dielectric plate having one or more chucking electrodes disposed therein, an upper surface for supporting a substrate, and a lower surface opposite the upper surface; a support plate bonded to the dielectric plate and having an outer ring extending radially outward beyond the dielectric plate, wherein the outer ring includes one or more fastener openings, and wherein the support plate includes one or more electrode feedthrough openings at an inner region of the support plate; and a base plate removably coupled to the support plate via the one or more fastener openings.

### FIELD

Embodiments of the present disclosure generally relate to substrate processing equipment.

### BACKGROUND

Substrate supports are used for providing support to substrates within substrate processing systems, such as a plasma processing chamber. A type of substrate support includes an electrostatic chuck (ESC) coupled to a lower assembly. An ESC generally includes one or more electrodes embedded within a ceramic chuck body to retain a substrate. The ESC may be used for mid and room temperature applications (˜90 to 200 Celsius). However, ESCs may become damaged or fail over time and replacement of an entire substrate support is expensive and leads to increased tool downtime. An ESC may be detachable from the lower assembly to reduce preventative maintenance time and reduce cost of replacement.

Accordingly, the inventors have provided improved substrate supports for use with mid or room temperature applications.

### SUMMARY

Embodiments of substrate supports are provided herein. In some embodiments, a substrate support includes: a dielectric plate having one or more chucking electrodes disposed therein, an upper surface for supporting a substrate, and a lower surface opposite the upper surface; a support plate bonded to the dielectric plate and having an outer ring extending radially outward beyond the dielectric plate, wherein the outer ring includes one or more fastener openings, and wherein the support plate includes one or more electrode feedthrough openings at an inner region of the support plate; and a base plate removably coupled to the support plate via the one or more fastener openings.

In some embodiments, a substrate support includes: a dielectric plate having one or more chucking electrodes disposed therein, an upper surface for supporting a substrate, and a lower surface opposite the upper surface; a support plate coupled to the lower surface of the dielectric plate and having an outer ring, wherein the outer ring includes one or more fastener openings extending through the outer ring, and wherein the support plate includes one or more electrode feedthrough openings at an inner region of the support plate; and a base plate removably coupled to the support plate via the one or more fastener openings.

In some embodiments, a process chamber includes: a chamber body defining an interior volume therein; and a substrate support disposed in the interior volume, the substrate support comprising: a dielectric plate having one or more chucking electrodes disposed therein, an upper surface for supporting a substrate, and a lower surface opposite the upper surface; a support plate bonded to the dielectric plate and having an outer ring extending radially outward beyond the dielectric plate, wherein the outer ring includes one or more fastener openings, and wherein the support plate includes one or more electrode feedthrough openings at an inner region of the support plate; and a lower assembly comprising a base plate removably coupled to the support plate via the one or more fastener openings, wherein the lower assembly is coupled to the support plate only via the one or more fastener openings.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic side view of a process chamber in accordance with at least some embodiments of the present disclosure.

FIG. 2 depicts a top isometric cross-sectional view of a substrate support in accordance with at least some embodiments of the present disclosure.

FIG. 3 depicts a top isometric view of a lower assembly of a substrate support in accordance with at least some embodiments of the present disclosure.

FIG. 4 depicts a top isometric view of an upper assembly of a substrate support in accordance with at least some embodiments of the present disclosure.

FIG. 5 depicts a bottom isometric view of a support plate in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of detachable substrate supports configured for mid or room temperature applications are provided herein. The substrate support provided herein generally includes an upper assembly removable coupled to a lower assembly for ease of service and replacement and for reduced cost of replacement of substrate support components. The upper assembly may advantageously be removably coupled to the lower assembly along an outer periphery of an interface therebetween. The upper assembly generally includes an electrostatic chuck configured to electrostatically retain a substrate to an upper surface thereof.

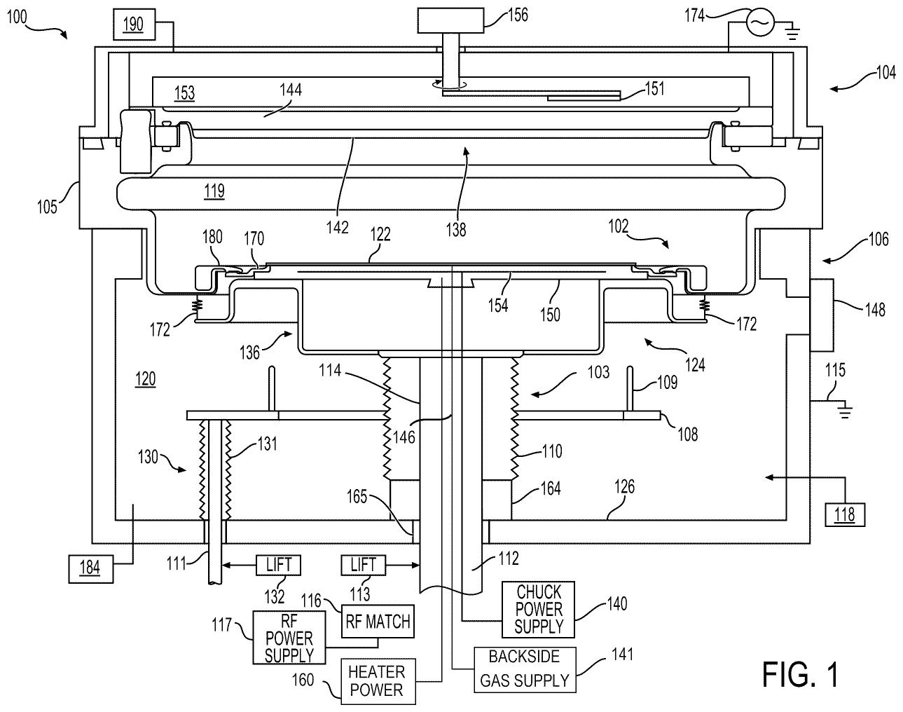

FIG. 1 depicts a schematic side view of a process chamber 100 having a substrate support in accordance with at least some embodiments of the present disclosure. In some embodiments, the process chamber 100 is a PVD chamber or preclean chamber. However, other types of processing chambers configured for different processes can also use or be modified for use with embodiments of the electrostatic chuck described herein.

The process chamber 100 is generally a vacuum chamber which is suitably adapted to maintain sub-atmospheric pressures within an interior volume 120 of the process chamber 100 during substrate processing. The process chamber 100 includes a chamber body 106 covered by a lid 104 which encloses a processing volume 119 located in the upper half of the interior volume 120. The process chamber 100 may also include a process shield 105 circumscribing various chamber components to prevent unwanted reaction between such components and ionized process material. The chamber body 106 and lid 104 may be made of metal, such as aluminum. The chamber body 106 may be grounded via a coupling to ground 115.

A substrate support 124 is disposed within the interior volume 120 to support and retain a substrate 122, such as a semiconductor wafer, for example, or other such substrate as may be electrostatically retained. The substrate support 124 may generally comprise an electrostatic chuck 150 disposed on a lower assembly 136. The electrostatic chuck 150 may be made of a ceramic material. The lower assembly 136 is coupled to a support assembly 103 for supporting the lower assembly 136 and the electrostatic chuck 150.

The support assembly 103 generally includes an inner tube 112 that is hollow and a bellows assembly 110 disposed about the inner tube 112. The inner tube 112 is configured to provide an RF delivery path from the RF bias power supply 117 to the electrostatic chuck 150. The inner tube 112 also provides a conduit to provide, for example, backside gases, process gases, fluids, coolants, power, auto capacitive tuner (ACT), or the like, to the electrostatic chuck 150. The bellows assembly 110 may include an outer tube 114 disposed about the inner tube 112. In some embodiments, the outer tube 114 is configured to provide an RF return path from the lower assembly 136. In some embodiments, a lower end of the inner tube 112 may protrude beyond a lower end of the outer tube 114 to facilitate electrical connection to the inner tube 112 and the outer tube 114.

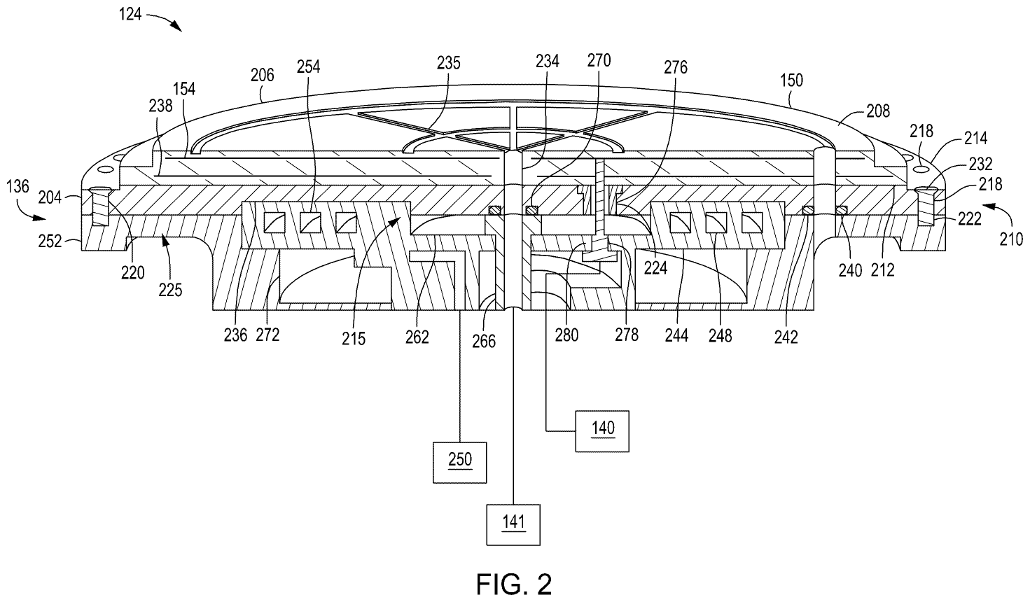

The electrostatic chuck 150 includes one or more chucking electrodes 154 disposed therein. A temperature of the electrostatic chuck 150 may be adjusted to control the temperature of the substrate 122. For example, the electrostatic chuck 150 may be heated using one or more resistive heating elements 238 (e.g., see FIG. 2) that are embedded, such as a resistive heater. In some embodiments, a thickness of the electrostatic chuck 150 may be about 6.0 mm or less.

In some embodiments, the inner tube 112 is coupled to a lift mechanism 113, such as an actuator or motor, which provides vertical movement of the electrostatic chuck 150 between an upper, processing position (as shown in FIG. 1) where the substrate 122 is elevated with respect to the slit valve 148 and a lower, transfer position (not shown) where the substrate 122 is aligned with the slit valve 148.

The bellows assembly 110 is coupled between the electrostatic chuck 150 and a bottom surface 126 of process chamber 100 to provide a flexible seal that allows vertical motion of the electrostatic chuck 150 while preventing loss of vacuum from within the process chamber 100. The bellows assembly 110 may also include a lower bellows flange 164 in contact with an o-ring 165 or other suitable sealing element which contacts the bottom surface 126 to help prevent loss of chamber vacuum. The bellows assembly 110 may facilitate or partially define an RF return path from the lower assembly 136.

The inner tube 112 provides a conduit for coupling a backside gas supply 141, a chucking power supply 140, a heater power supply 160, to the electrostatic chuck 150. The backside gas supply 141 is disposed outside of the chamber body 106 and supplies gas to the electrostatic chuck 150 via a gas conduit 146 to control the temperature or pressure and/or a temperature profile or pressure profile on the support surface of the electrostatic chuck 150 during use. In some embodiments, RF power supply 174 and RF bias power supply 117 are coupled to the electrostatic chuck 150 via respective RF match networks (only RF match network 116 shown). In some embodiments, the substrate support 124 may alternatively include AC, DC, or RF bias power.

The RF delivery path and the RF return path are arranged in a coaxial manner along the support assembly 103. For example, the RF delivery path extends along the inner tube 112, which acts as an RF electrode. The inner tube 112 may be maintained at a constant temperature. The RF return path extends along the outer tube 114 disposed about the inner tube 112. The arrangement of the inner tube 112 and the outer tube 114 creates a neutral or field free region within the inner tube 112, reducing RF losses due to RF coupling of electrostatic chuck wires, heater wires, thermocouple wires, and the like.

A substrate lift 130 can include lift pins 109 mounted on a platform 108 connected to a shaft 111 which is coupled to a second lift mechanism 132 for raising and lowering the substrate lift 130 so that the substrate 122 may be placed on or removed from the electrostatic chuck 150. The electrostatic chuck 150 may include through holes to receive the lift pins 109. A bellows assembly 131 is coupled between the substrate lift 130 and bottom surface 126 to provide a flexible seal which maintains the process chamber vacuum during vertical motion of the substrate lift 130.

The process chamber 100 is coupled to and in fluid communication with a vacuum system 184 which includes a throttle valve (not shown) and vacuum pump (not shown) which are used to exhaust the process chamber 100. The pressure inside the process chamber 100 may be regulated by adjusting the throttle valve and/or vacuum pump. The process chamber 100 is also coupled to and in fluid communication with a process gas supply 118 which may supply one or more process gases to the process chamber 100 for processing the substrate 122 disposed therein.

A target 138 is disposed in the processing volume 119 opposite the substrate support 124 to at least partially define a process volume therebetween. The target 138 includes a cathode surface defined by processing volume facing surfaces of the target 138. The substrate support 124 has a support surface having a plane substantially parallel to a sputtering surface of the target 138. The target 138 is connected to one or both of a DC power source 190 and/or the RF power supply 174. The DC power source 190 can apply a bias voltage to the target 138 relative to the process shield 105.

The target 138 comprises a sputtering plate 142 mounted to a backing plate 144. The sputtering plate 142 comprises a material to be sputtered, or deposited, onto the substrate 122. The backing plate 144 is made from a metal, such as, for example, stainless steel, aluminum, copper-chromium, or copper-zinc. The backing plate 144 can be made from a material having a thermal conductivity that is sufficiently high to dissipate the heat generated in the target 138, which forms eddy currents that arise in the sputtering plate 142 and the backing plate 144 and also from the bombardment of energetic ions from generated plasma onto the sputtering plate 142.

In some embodiments, the process chamber 100 includes a magnetic field generator 156 to shape a magnetic field about the target 138 to improve sputtering of the target 138. The capacitively generated plasma may be enhanced by the magnetic field generator 156 in which, for example, a plurality of magnets 151 (e.g., permanent magnets or electromagnetic coils) may provide a magnetic field in the process chamber 100 that has a rotating magnetic field having a rotational axis that is perpendicular to the plane of the substrate 122. The magnetic field generator 156 may include a motor assembly that rotates the plurality of magnets 151. The magnetic field generator 156 may generate a magnetic field near the target 138 to increase an ion density in the processing volume 119 to improve the sputtering of the target material. The plurality of magnets 151 may be disposed in a cavity 153 in the lid 104. A coolant such as water may be disposed in or circulated through the cavity 153 to cool the target 138.

The process chamber 100 includes a process kit 102 circumscribing various chamber components to prevent unwanted reaction between such components and ionized process material. The process kit 102 includes a process shield 105 surrounding the substrate support 124 and the target 138 to at least partially define the processing volume 119. For example, the process shield 105 may define an outer boundary of the processing volume 119. In some embodiments, the process shield 105 is made of a metal such as aluminum.

In some embodiments, the process kit 102 includes a deposition ring 170 that rests on an outer edge of the electrostatic chuck 150. In some embodiments, the process kit 102 includes a cover ring 180 disposed on the process shield 105 to form a tortuous gas flow path therebetween. In some embodiments, in the processing position, a radially inner portion of the cover ring 180 rests on the deposition ring 170 to reduce or prevent plasma leak therebetween.

In some embodiments, a plurality of ground loops 172 are disposed between the process shield 105 and the lower assembly 136. The ground loops 172 may generally comprise a loop of conductive material, or alternatively, conductive straps, spring members, or the like, configured to ground the process shield 105 to the lower assembly 136 when the substrate support 124 is in the processing position. In some embodiments, the plurality of ground loops 172 are coupled to an outer lip of the lower assembly 136 so that in the processing position, the ground loops 172 contact the process shield 105 to ground the process shield 105. In some embodiments, in the transfer position, the ground loops 172 are spaced from the process shield 105.

The process chamber 100 is coupled to and is in fluid communication with a vacuum system 19 which includes a throttle valve (not shown) and vacuum pump (not shown) which are used to exhaust the process chamber 100. The pressure inside the process chamber 100 may be regulated by adjusting the throttle valve and/or vacuum pump. The process chamber 100 is also coupled to and in fluid communication with a process gas supply 118 which may supply one or more process gases to the process chamber 100 for processing the substrate 122 disposed therein. A slit valve 148 may be coupled to the chamber body 106 and aligned with an opening in a sidewall of the chamber body 106 to facilitate transferring the substrate 122 into and out of the chamber body 106.

In use, while the DC power source 190 supplies power to the target 138 and other chamber components connected to the DC power source 190, the RF power supply 174 energizes the sputtering gas (e.g., from the process gas supply 118) to form a plasma of the sputtering gas. The plasma formed impinges upon and bombards the sputtering surface of the target 138 to sputter material off the target 138 onto the substrate 122. In some embodiments, a plurality of RF power sources may be provided (i.e., two or more) to provide RF energy in a plurality of the above frequencies. An additional RF power source, (e.g., RF bias power supply 117) can also be used to supply a bias voltage to the substrate support 124 to attract ions from the plasma towards the substrate 122.

FIG. 2 depicts a top isometric cross-sectional view of a substrate support 124 in accordance with at least some embodiments of the present disclosure. The substrate support 124 generally includes an upper assembly 210 removably coupled to the lower assembly 136. The upper assembly 210 comprises the electrostatic chuck 150 coupled to a support plate 204. The electrostatic chuck 150 includes a dielectric plate 206 having the one or more chucking electrodes 154 disposed therein, an upper surface 208 for supporting a substrate, and a lower surface 212 opposite the upper surface. In some embodiments, the support plate 204 is bonded to the dielectric plate 206. In some embodiments, the support plate 204 comprises a metal material. In some embodiments, the support plate 204 is made of aluminum and silicon carbide. In some embodiments, the support plate 204 is thicker than the dielectric plate 206 to advantageously support the dielectric plate 206 and reduce warpage of the dielectric plate 206.

The support plate 204 includes an outer ring 214 extending radially outward beyond the dielectric plate 206. In some embodiments, the upper assembly 210 is removably coupled to the lower assembly 136 via the outer ring 214. For example, the outer ring 214 may include one or more fastener openings 218 aligned with one or more fastener openings 222 in the lower assembly 136. One or more fasteners 220 corresponding to the one or more fastener openings 218 may be used to removably couple the upper assembly 210 to the lower assembly 136. In some embodiments, the one or more fastener openings 218 extend entirely through the outer ring 214. In some embodiments, the one or more fastener openings 222 extend only partially through the lower assembly 136. In some embodiments, the one or more fastener openings 222 extend through the lower assembly 136. In some embodiments, the one or more fastener openings 222 extend through the lower assembly 136 and the one or more fastener openings 218 extend only partially through the outer ring 214 from a lower surface thereof. In some embodiments, the upper assembly 210 is fastened to the lower assembly 136 only via the outer ring 214.

In some embodiments, the support plate 204 includes an upper peripheral notch 228. For example, the upper peripheral notch 228 may define the outer ring 214 of the support plate 204. In some embodiments, the one or more fastener openings 218 may include a countersink so that the one or more fasteners 220 do not protrude, or only slightly protrude, from an upper surface of the outer ring 214.

The support plate 204 includes an inner region 215 and an outer region 225. In some embodiments, the support plate 204 includes one or more electrode feedthrough openings 224 at the inner region 215. In some embodiments, a lower surface of the support plate 204 includes a recessed region 236 disposed between the outer ring 214 and the inner region 215. In some embodiments, the recessed region 236 is an annular region sized to accommodate a portion of the lower assembly 136.

In some embodiments, a plurality of lift pin openings 240 are disposed through the outer region 225 of the support plate 204. In some embodiments, an o-ring 242 is disposed around each of the lift pin openings 240. In some embodiments, a backside gas channel 234 extends through the inner region 215 of the support plate 204 and through the dielectric plate 206. The backside gas channel 234 is coupled to the backside gas supply 141. In some embodiments, the backside gas channel 234 extends through a center of the dielectric plate 206. A plurality of gas grooves 235 may be disposed on the upper surface 208 of the dielectric plate 206 in a suitable pattern to distribute gas from the backside gas channel 234 across the upper surface 208. For example, the plurality of gas grooves 235 may extend in radial and annular directions.

In some embodiments, the dielectric plate 206 includes one or more resistive heating elements 238 disposed therein to heat the dielectric plate 206. In some embodiments, the one or more resistive heating elements 238 are arranged as an inner heater and an outer heater disposed radially outward of the inner heater. In some embodiments, the one or more resistive heating elements 238 are disposed vertically below the one or more chucking electrodes 154. In some embodiments, the one or more resistive heating elements 238 extend radially beyond the one or more chucking electrodes 154 so that the upper surface 208 is more uniformly heated.

The lower assembly 136 includes a base plate 252 coupled to the upper assembly 210. For example, the base plate 252 may be removably coupled to the support plate 204 via the one or more fastener openings 218. In some embodiments, the lower assembly 136 is coupled to the support plate 204 only via the one or more fastener openings 218. The inventors have observed that for mid or room temperature applications, the upper assembly 210 is removably coupled to the lower assembly 136 at locations radially outward of the dielectric plate 206. In some embodiments, the base plate 252 comprises a bowl shape defining a central cavity 272.

In some embodiments, a cooling plate 244 is coupled to, or abuts, the support plate 204 on a side opposite the dielectric plate 206. The cooling plate 244 includes one or more cooling channels 248 configured to circulate a fluid therethrough. The one or more cooling channels 248 are fluidly coupled to a coolant source 250, such as a water source or other suitable fluid. In some embodiments, an outer diameter of the cooling plate 244 is less than an outer diameter of the support plate 204 and the dielectric plate 206. In some embodiments, the cooling plate 244 at least partially extends into the central cavity 272 of the base plate 252. In some embodiments, the cooling plate 244 is located between the support plate 204 and the base plate 252.

In some embodiments, an upper surface 254 of the cooling plate 244 includes a central recess 262 and the one or more cooling channels 248 are disposed radially outward of the central recess 262. In some embodiments, the upper surface 254 of the cooling plate 244 that is disposed radially outward of the central recess 262 extends into the recessed region 236 of the support plate 204 and contacts the lower surface of the support plate 204. In some embodiments, the support plate 204 abuts the cooling plate 244 at the recessed region 236 and is spaced from the cooling plate 244 at the inner region 215. In some embodiments, the lower assembly 136 includes an inner tube 266 coupled to the cooling plate 244 and extends at least partially through the central recess 262. The backside gas channel 234 extends through the inner tube 266. In some embodiments, an o-ring 270 is disposed about the backside gas channel 234 between the support plate 204 and the inner tube 266.

The dielectric plate 206 may include one or more terminals 276 for coupling the one or more chucking electrodes 154 to the chucking power supply 140. For example, the lower surface 212 of the dielectric plate 206 includes a first terminal of the one or more terminals 276 coupled to a first chucking electrode of the one or more chucking electrodes 154 and a second terminal coupled to a second chucking electrode of the one or more chucking electrodes 154. The lower assembly 136 may include one or more electrical feedthroughs 278 coupled to corresponding ones of the one or more terminals 276. The one or more terminals 276 may extend through the one or more electrode feedthrough openings 224 in the support plate 204. In some embodiments, the cooling plate 244 includes one or more electrode feedthroughs 280 aligned with the one or more electrode feedthrough openings 224 of the support plate 204.

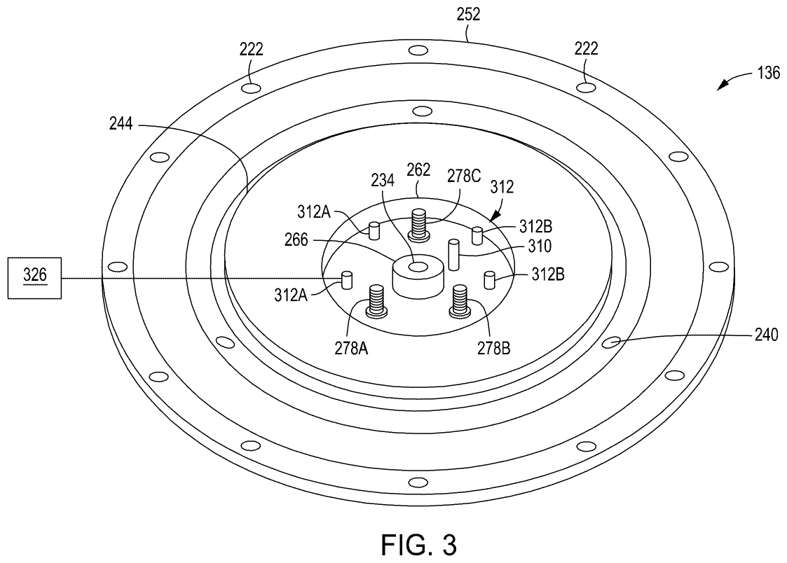

FIG. 3 depicts a top isometric view of a lower assembly 136 of a substrate support in accordance with at least some embodiments of the present disclosure. In some embodiments, the one or more electrical feedthroughs 278 include a first feedthrough 278A and a second feedthrough 278B 278C for coupling to corresponding terminals of the one or more terminals 276 to configure the electrostatic chuck 150 as a bipolar electrostatic chuck. In some embodiments, the one or more electrical feedthroughs 278 include a third feedthrough 278C for coupling to a corresponding terminal of the one or more terminals 276 for a center tap for sensing a reference DC voltage. In some embodiments, a thermocouple 310 extends through the cooling plate and is configured to measure a temperature of the substrate support 124 (e.g., temperature of dielectric plate 206).

In some embodiments, power leads 312 are disposed in the lower assembly 136 and configured to provide power to the one or more resistive heating elements 238 from a heater power source 326. For example, the power leads 312 may comprise a pair of first lead lines 312A for providing power to a first heating element of the one or more resistive heating elements 238. The power leads 312 may comprise a pair of second lead lines 312B for providing power to a second heating element. In some embodiments, the first heating element may be for an inner heater and the second heating element may be an outer heater. In some embodiments, the power leads 312 are disposed in the central recess 262.

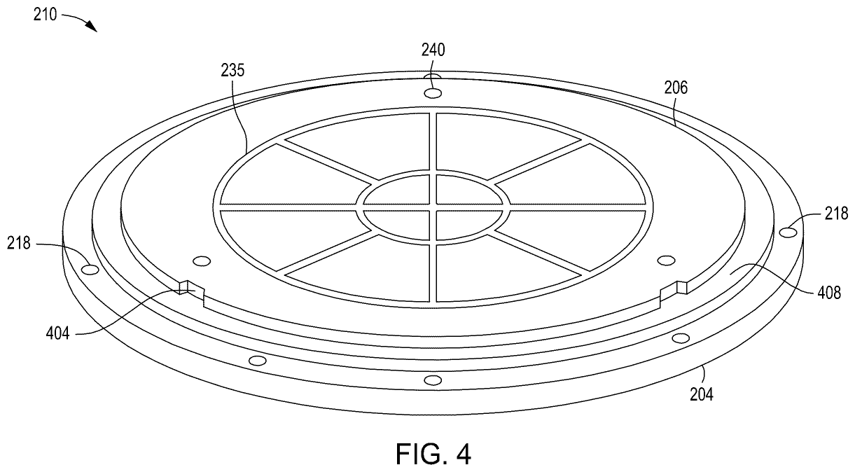

FIG. 4 depicts a top isometric view of an upper assembly 210 of a substrate support in accordance with at least some embodiments of the present disclosure. In some embodiments, the dielectric plate 206 includes a peripheral notch 408. In some embodiments, the dielectric plate 206 includes one or more alignment notches 404 disposed along sidewalls of the peripheral notch 408 for aligning the process kit 102.

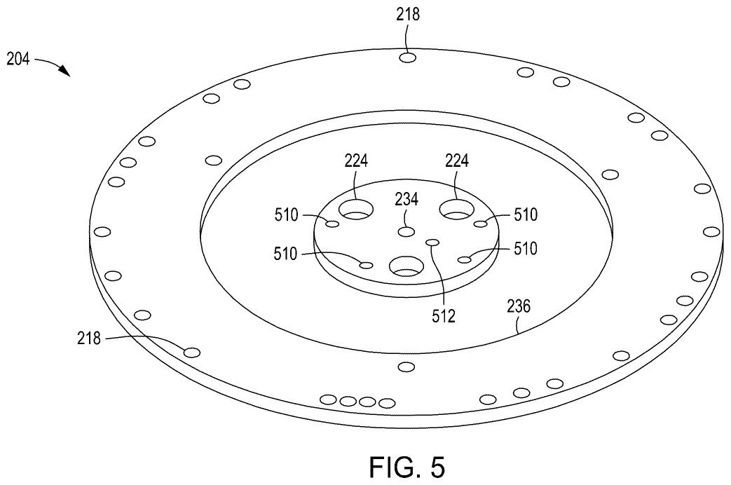

FIG. 5 depicts a bottom isometric view of a support plate in accordance with at least some embodiments of the present disclosure. In some embodiments, the support plate 204 includes a plurality of heater feedthrough openings 510 for the power leads 312 for the one or more resistive heating elements 238. In some embodiments, the plurality of heater feedthrough openings 510 are disposed radially outward of the one or more electrode feedthrough openings 224. In some embodiments, the plurality of heater feedthrough openings 510 are disposed in the inner region 215 of the support plate 204. In some embodiments, the support plate 204 includes an opening 512 for the thermocouple 310. In some embodiments, the opening 512 is disposed in the inner region 215.

While the foregoing is directed to embodiments of the present disclosure, other and further embodiments of the disclosure may be devised without departing from the basic scope thereof.

1. A substrate support, comprising:
a dielectric plate having one or more chucking electrodes disposed therein, an upper surface for supporting a substrate, and a lower surface opposite the upper surface;
a support plate bonded to the dielectric plate and having an outer ring extending radially outward beyond the dielectric plate, wherein the outer ring includes one or more fastener openings, and wherein the support plate includes one or more electrode feedthrough openings at an inner region of the support plate; and
a base plate removably coupled to the support plate via the one or more fastener openings.

2. The substrate support of claim 1, wherein the dielectric plate include one or more resistive heating elements disposed therein.

3. The substrate support of claim 2, wherein the support plate includes a plurality of heater feedthrough openings for the one or more resistive heating elements.

4. The substrate support of claim 1, wherein the support plate includes an upper peripheral notch.

5. The substrate support of claim 1, wherein a lower surface of the support plate includes a recessed region disposed between the outer ring and the inner region.

6. The substrate support of claim 1, further comprising a plurality of lift pin openings disposed through an outer region of the support plate.

7. The substrate support of claim 1, further comprising a backside gas channel extending through the inner region of the support plate and through the dielectric plate.

8. The substrate support of claim 1, wherein the support plate comprises aluminum and silicon carbide.

9. The substrate support of claim 1, wherein the lower surface of the dielectric plate includes a first terminal coupled to a first chucking electrode of the one or more chucking electrodes and a second terminal coupled to a second chucking electrode of the one or more chucking electrodes.

10. A substrate support, comprising:
a dielectric plate having one or more chucking electrodes disposed therein, an upper surface for supporting a substrate, and a lower surface opposite the upper surface;
a support plate coupled to the lower surface of the dielectric plate and having an outer ring, wherein the outer ring includes one or more fastener openings extending through the outer ring, and wherein the support plate includes one or more electrode feedthrough openings at an inner region of the support plate; and
a base plate removably coupled to the support plate via the one or more fastener openings.

11. The substrate support of claim 10, further comprising a cooling plate coupled to the support plate on a side opposite the dielectric plate, wherein the base plate comprises a bowl shape defining a central cavity, and wherein the cooling plate is disposed in the central cavity.

12. The substrate support of claim 11, wherein the cooling plate includes one or more cooling channels configured to circulate a fluid therethrough, wherein an upper surface of the cooling plate includes a central recess and the one or more cooling channels are disposed radially outward of the central recess.

13. The substrate support of claim 11, wherein the cooling plate includes one or more electrode feedthroughs aligned with the one or more electrode feedthroughs of the support plate.

14. The substrate support of claim 11, wherein the lower surface of the support plate includes a recess and an upper surface of the cooling plate extends into the recess.

15. The substrate support of claim 10, further comprising one or more resistive heating elements disposed in the dielectric plate, and further comprising a backside gas channel disposed in the dielectric plate.

16. A process chamber, comprising:
a chamber body defining an interior volume therein; and
a substrate support disposed in the interior volume, the substrate support comprising:
a dielectric plate having one or more chucking electrodes disposed therein, an upper surface for supporting a substrate, and a lower surface opposite the upper surface;
a support plate bonded to the dielectric plate and having an outer ring extending radially outward beyond the dielectric plate, wherein the outer ring includes one or more fastener openings, and wherein the support plate includes one or more electrode feedthrough openings at an inner region of the support plate; and
a lower assembly comprising a base plate removably coupled to the support plate via the one or more fastener openings, wherein the lower assembly is coupled to the support plate only via the one or more fastener openings.

17. The process chamber of claim 16, further comprising:
a backside gas channel extending through the support plate and the dielectric plate; and
a backside gas supply coupled to the backside gas channel.

18. The process chamber of claim 16, further comprising:
one or more resistive heating elements disposed in the dielectric plate; and
a power source coupled to the one or more resistive heating elements.

19. The process chamber of claim 16, wherein the support plate include lift pin openings and further comprising an o-ring disposed around each of the lift pin openings between the base plate and the support plate.

20. The process chamber of claim 16, wherein the lower assembly further comprises a cooling plate disposed between the base plate and the support plate.
